(19) United States
(12) Patent Application Publication
(10) Pub. No.: US 2016/0134264 A1
(43) Pub. Date: May 12, 2016

(54) META-STABILITY PREVENTION FOR OSCILLATORS

(71) Applicant: Lattice Semiconductor Corporation, Hillsboro, OR (US)

(72) Inventors: Maryam Shahbazi, Alamo, CA (US); Hamid Ghezel, Santa Cruz, CA (US); Ban Pak Wong, Milpitas, CA (US); Magathi Jayaram, San Jose, CA (US)

(21) Appl. No.: 14/535,351

(22) Filed: Nov. 7, 2014

(51) Int. Cl. H03K 3/03

(52) U.S. Cl. CPC H03K 3/0315

(57) ABSTRACT

In an integrated circuit, meta-stability prevention circuitry prevents an oscillator, such as a current-controlled oscillator having a ring of differential inverters, from being turned on, for example, during power up, until after the power-supply voltage is sufficiently high for the oscillator ring to achieve oscillation without going into a meta-stable state. In one implementation, a level detector monitors the power-supply voltage level and generates a logic signal indicating whether or not the power-supply voltage level is sufficiently high. That logic signal and a conventional chip-level power-down control signal are applied to logic circuitry that generates control signals for one or more switch transistors that selectively turn on and off the oscillator ring.

### BACKGROUND

1. Field of the Invention

The present invention relates to electronics and, more specifically but not exclusively, to current-controlled oscillators.

2. Description of the Related Art

This section introduces aspects that may help facilitate a better understanding of the invention. Accordingly, the statements of this section are to be read in this light and are not to be understood as admissions about what is prior art or what is not prior art.

FIG. 1 shows a schematic circuit diagram of a conventional current controlled oscillator (ICO) 100. ICO 100 comprises three differential inverters 112 connected in a ring 110 and an output buffer 120 connected to receive the two output signals clkoutp, clkoutn from the third inverter. When ICO 100 is running, oscillator ring 110 oscillates to generate the two output signals clkoutp, clkoutn in the form of complementary clock signals. Although not shown in FIG. 1, ICO 100 is part of a larger integrated circuit, such as, for example, a field-programmable gate array (FPGA) or application-specific integrated circuit (ASIC), that has other circuitry, some of which uses the clock signals generated by ICO 100.

To turn ICO 100 on and off, two complementary power-down control signals pwdn and pwdnb are applied to the gates of two switch transistors N1 and P1. To turn on ICO 100, pwdn is driven low to turn off n-type transistor N1, and pwdnb is driven high to turn off p-type transistor P1. In that case, the two inputs to buffer 120 are isolated from a node of the regulated power supply voltage vcca_reg and ground, and oscillator ring 110 is free to oscillate. To turn off ICO 100, pwdn is driven high to turn on transistor N1, and pwdnb is driven low to turn on transistor P1. In that case, the two inputs to buffer 120 are respectively connected to vcca_reg (via P1) and ground (via N1), oscillator ring 110 will cease to oscillate, buffer output signal clkoutp will be driven high (i.e., to vcca_reg), and buffer output signal clkoutn will be driven low (i.e., to ground).

Note that, in many integrated circuits, pwdn and pwdnb are chip-level control signals generated by on-chip circuitry for use by many different sets of circuitry within the integrated circuit in addition to ICO 100.

When the integrated circuit containing ICO 100 is initially turned on, the regulated power supply voltage vcca_reg rises relatively slowly from zero volts to its steady-state operating voltage level due to the large decoupling capacitance C_{large}. At the same time, the oscillator comes out of power down as the outputs of third inverter 112 are released from being clamped to vcca_reg and ground but before the power supply voltage vcca_reg has reached or even substantially approached its steady-state operating voltage level. This could result in the regenerative differential inverters 112 of oscillator ring 110 going into a meta-stable state for an extended period of time or even indefinitely, resulting in no desired oscillation at the output of buffer 120.

### BRIEF DESCRIPTION OF THE DRAWINGS

Other embodiments of the invention will become more fully apparent from the following detailed description, the appended claims, and the accompanying drawings in which like reference numerals identify similar or identical elements.

FIG. 1 shows a schematic circuit diagram of a conventional current controlled oscillator (ICO);

FIG. 2 shows a schematic block diagram of one possible implementation of meta-stability prevention circuitry;

FIG. 3 shows a schematic block diagram of an ICO according to an embodiment of the present invention;

FIG. 4 contains Table I, which describes the operations of the ICO of FIG. 3 with the meta-stability prevention functionality of the circuitry of FIG. 2; and

FIG. 5 shows a schematic circuit diagram of one possible implementation of the power OK detector of FIG. 2.

### DETAILED DESCRIPTION

According to certain embodiments of the present invention, instead of applying the standard complementary power-down control signals pwdn, pwdnb directly to the gates of the two switch transistors N1, P1, as in FIG. 1, meta-stability prevention circuitry is included to ensure that the switch transistors are not turned off until after the power-supply voltage vcca_reg has reached a sufficiently high voltage level to ensure that the oscillator ring will oscillate and not get stuck in a meta-stable state.

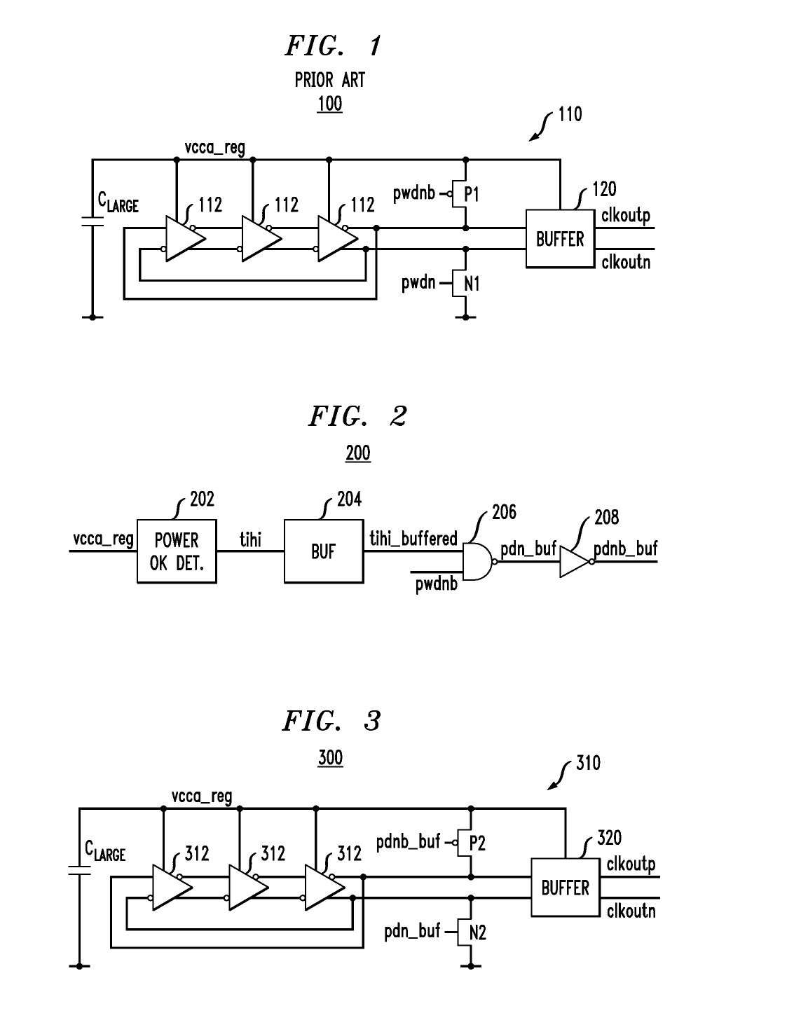

FIG. 2 shows a schematic block diagram of one possible implementation of meta-stability prevention circuitry 200 used to generate two complementary buffered control signals pdn_buf and pdnb_buf, while FIG. 3 shows a schematic block diagram of ICO 300, whose switch transistors N2 and P2 are controlled by those two buffered control signals. In all other respects, ICO 300 of FIG. 3 is identical to ICO 100 of FIG. 1, with oscillator ring 310 of differential inverters 312 and output buffer 320 being analogous to oscillator ring 110 of differential inverters 112 and output buffer 120 of FIG. 1.

Referring to FIG. 2, power OK detector 202 is a level detector that receives the analog power-supply voltage vcca_reg and generates a signal tihi, which is then buffered through buffer 204 to produce signal tihi_buffered, a digital signal which indicates whether or not vcca_reg is sufficiently close to its desired operating voltage level. If so, then tihi_buffered is high (i.e., logic 1); otherwise, tihi_buffered is low (i.e., logic 0).

Signal tihi_buffered is applied to NAND gate 206 along with the conventional power-down control signal pwdnb described in the Background section. The output of NAND gate 206 is a new, sufficiently delayed power-down control signal pdn_buf, which is applied to inverter 208 to generate a new, complementary, buffered power-down control signal pdnb_buf. As shown in FIG. 3, pdn_buf is applied to switch transistor N2, while pdnb_buf is applied to switch transistor P2.

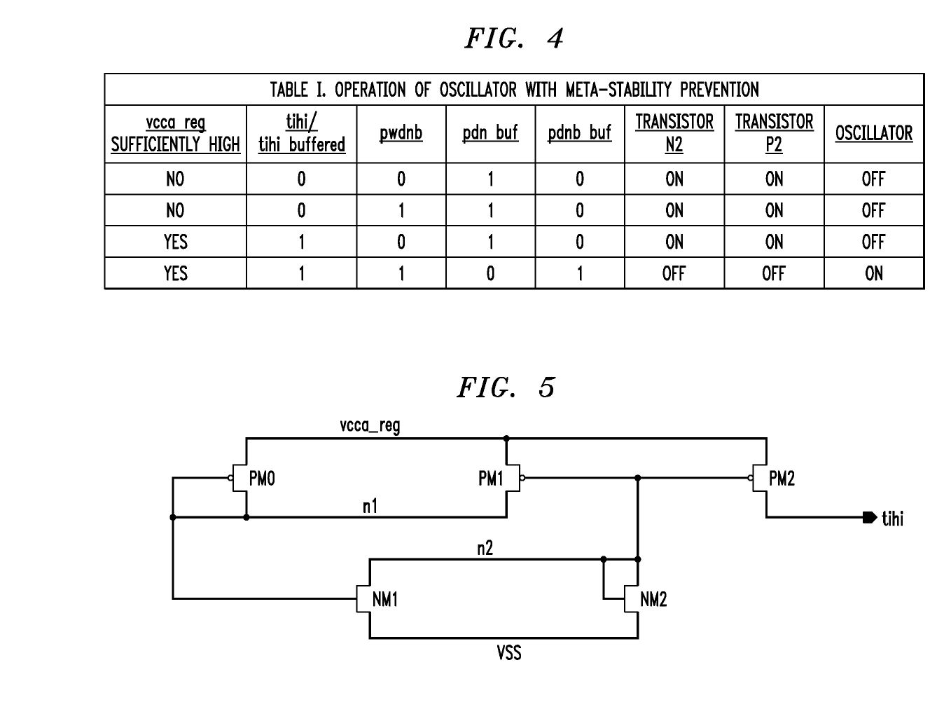

FIG. 4 contains Table I, which describes the operations of ICO 300 of FIG. 3 with the meta-stability prevention functionality of circuitry 200 of FIG. 2. As indicated in Table I, when power OK detector 202 determines that vcca_reg is not sufficiently high, then switch transistors N2 and P2 will both be ON, and oscillator ring 310 will not oscillate, independent of whether conventional power-down control signal pwdnb is high or low. In addition, when power OK detector 202 determines that vcca_reg is sufficiently high, but pwdnb is low, then switch transistors N2 and P2 will still both be ON, and oscillator ring 310 will still not oscillate. When (i) power OK detector 202 determines that vcca_reg is sufficiently high and (ii) pwdnb is high, only then will switch transistors N2 and P2 both be OFF and, as a result, oscillator ring 310 will oscillate.

When the integrated circuit comprising ICO 300 is initially turned on, the values of pwdnb, pdn_buf, and pdnb_buf are all low, and transistors N2 and P2 are both off. Nevertheless, N2 and P2 turn on quickly during power up, because digital circuitry controls the “global” signals pwdn and pwdnb. There is nothing slowing down the digital circuitry, such as a large capacitor to charge, so, even though it's not actually instantaneous, for all practical purposes, pwdn and pwdnb immediately achieve their intended levels, and N2 and P2 are turned on/off accordingly.

During power up, while vcca_reg is rising from zero volts, if the conventional control signal pwdnb is driven high before power OK detector 202 has determined that vcca_reg is sufficiently close to its desired operating voltage level, then switch transistors N2 and P2 will still be ON preventing oscillator ring 310 from attempting to oscillate with an insufficient power supply voltage. Only after power OK detector 202 determines that vcca_reg is sufficiently high will the two switch transistors be turned OFF, thereby allowing oscillator ring 310 to oscillate with a sufficiently high power supply voltage that ensures that the oscillator ring will not enter a meta-stable state.

FIG. 5 shows a schematic circuit diagram of one possible implementation of power OK detector 202 of FIG. 2. Power OK detector 202 is designed such that its output tihi rises with a delay as its input vcca_reg rises, where tihi functions as a level-detector signal that indicates when vcca_reg has reached a high enough value for oscillation of ICO 300 to begin.

Transistor PM0 is a diode-connected PMOS device that is either off or in saturation when on. Since the drain of PM0 is connected to the gate of NMOS device NM1, there is no sink for current through PM0, which functions as a diode that tends to maintain a zero voltage across its terminals since there is no sink or source of current through it. This means node n1 will track vcca_reg as vcca_reg rises. As n1 rises, NM1 will eventually turn on, which maintains node n2 at vss (i.e., ground).

The same may be said for diode-connected NMOS device NM2, whose drain is connected to the gates of PMOS devices PM1 and PM2. Since there is no current source to NM2, the voltage across its source and drain remains near zero. This means that node n2 tracks ground, which means that the gates of PM1 and PM2 are zero. As such, PM1 and PM2 will be on when their source-gate voltage (Vsg) is greater than their threshold voltage Vt. When Vsg is less than Vt, tihi remains near ground, but, as Vsg rises with rising vcca_reg, PM1 and PM2 enter saturation, and tihi tracks vcca_reg more closely. In this exemplary embodiment, the desired operating voltage level for vcca_reg is about 1.1 V, and power OK detector 202 will determine that a voltage level of about 0.8V is sufficient for turning on oscillator ring 300 without risking meta-stability. Since tihi is buffered at buffer 204, the resulting tihi_buffered will rise substantially instantaneously in response to vcca_reg passing that 0.8V threshold.

Although the implementation of power OK detector 202 shown in FIG. 5 includes transistor PM1, power OK detector 202 can also be implemented without transistor PM1. This is just one embodiment to achieve the desired delay in putting the de-assertion of the power down signal into effect. Other embodiments with fewer transistors can be explored.

Although the present invention has been described in the context of a particular current-controlled oscillator 300 of FIG. 3 having three differential inverter stages 312, those skilled in the art will understand that the present invention is not so limited. For example, the present invention can be implemented in the context of oscillators other than current-controlled oscillators, such as voltage-controlled oscillators, and/or oscillators having single-ended inverter stages instead of differential inverter stages, and/or oscillators having numbers of inverter stages other than three.

In ICO 300, two switch transistors N2 and P2 are provided to turn on and off the oscillator. In other embodiments, only one switch transistor might be needed to achieve the same oscillator-control functionality.

Furthermore, the present invention has been described in the context of meta-stability prevention circuitry 200 of FIG. 2 having a particular set of logic. Those skilled in the art will understand that other logic designs can achieve the same functionality as circuitry 200. Similarly, power OK detector 202 of FIG. 2 can be designed differently from that shown in the exemplary embodiment of FIG. 5. In general, any suitable level-detector design may be employed. For example, in theory, a comparator-based level detector could be used, but such a design would be relatively large and power hungry. Advantages of the 5-transistor design of FIG. 5 include it being smaller and using less power than such comparator-based designs.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

Transistors are typically shown as single devices for illustrative purposes. However, it is understood by those with skill in the art that transistors will have various sizes (e.g., gate width and length) and characteristics (e.g., threshold voltage, gain, etc.) and may consist of multiple transistors coupled in parallel to get desired electrical characteristics from the combination. Further, the illustrated transistors may be composite transistors.

Unless explicitly stated otherwise, each numerical value and range should be interpreted as being approximate as if the word “about” or “approximately” preceded the value or range.

It will be further understood that various changes in the details, materials, and arrangements of the parts which have been described and illustrated in order to explain embodiments of this invention may be made by those skilled in the art without departing from embodiments of the invention encompassed by the following claims.

In this specification including any claims, the term “each” may be used to refer to one or more specified characteristics of a plurality of previously recited elements or steps. When used with the open-ended term “comprising,” the recitation of the term “each” does not exclude additional, unrecited elements or steps. Thus, it will be understood that an apparatus may have additional, unrecited elements and a method may have additional, unrecited steps, where the additional, unrecited elements or steps do not have the one or more specified characteristics.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

The embodiments covered by the claims in this application are limited to embodiments that (1) are enabled by this specification and (2) correspond to statutory subject matter. Non-enabled embodiments and embodiments that correspond to non-statutory subject matter are explicitly disclaimed even if they fall within the scope of the claims.

1. An integrated circuit comprising:
a ring oscillator connected to a power-supply voltage node;
switch circuitry configured to selectively enable the ring oscillator to oscillate; and
meta-stability prevention circuitry configured to prevent the switch circuitry from enabling the ring oscillator to oscillate until after the meta-stability prevention circuitry determines that a voltage at the power-supply voltage node is sufficient to prevent the ring oscillator from entering a meta-stable state,
wherein the meta-stability prevention circuitry comprises:
level-detector circuitry configured to generate a “power OK” signal indicating whether the power-supply voltage is sufficiently high; and
logic circuitry connected to receive a chip-level power-down control signal and the “power OK” signal and generate one or more control signals for the switch circuitry.

2. The integrated circuit of claim 1, wherein the ring oscillator comprises a ring of inverters.

3. The integrated circuit of claim 2, wherein the inverters are differential inverters.

4. The integrated circuit of claim 1, wherein the switch circuitry comprises:
an n-type switch transistor connected between the ring oscillator and ground; and
a p-type switch transistor connected between the ring oscillator and the power-supply voltage.

5. (canceled)

6. The integrated circuit of claim 1, wherein the level-detector circuitry comprises:
a power OK detector configured to generate the “power OK” signal; and
a buffer configured to generate the buffered “power OK” signal from the “power OK” signal.

7. The integrated circuit of claim 6, wherein the power OK detector comprises:
a diode-connected, first p-type device whose source is connected to the power-supply voltage;
a first n-type device whose source is connected to ground and whose gate is connected to the drain of the diode-connected, first p-type device;
a diode-connected, second n-type device whose source is connected to ground; and
a second p-type device whose source is connected to the power-supply voltage, whose gate is connected to the drain of the diode-connected, second n-type device, and whose drain voltage is the analog “power OK” signal.

8. The integrated circuit of claim 7, wherein the power OK detector further comprises:
a third p-type device whose source is connected to the power-supply voltage, whose gate is connected to the drain of the diode-connected, second n-type device, and whose drain is connected to the gate of the first n-type device.

9. The integrated circuit of claim 1, wherein the logic circuitry comprises:
a NAND gate connected to receive the chip-level power-down control signal and the “power OK” signal and generate a first control signal for the switch circuitry; and
an inverter connected to receive the first control signal and generate a second control signal for the switch circuitry.

10. The integrated circuit of claim 1, wherein the integrated circuit is a field-programmable gate array.

11. The integrated circuit of claim 1, wherein:
the ring oscillator comprises a ring of differential inverters;
the switch circuitry comprises:
an n-type switch transistor connected between the ring oscillator and ground; and
a p-type switch transistor connected between the ring oscillator and the power-supply voltage; and
the level-detector circuitry comprises:
a power OK detector configured to generate the analog “power OK” signal; and
a buffer configured to generate a buffered “power OK” signal from the “power OK” signal; and
the power OK detector comprises:
a diode-connected, first p-type device whose source is connected to the power-supply voltage;
a first n-type device whose source is connected to ground and whose gate is connected to the drain of the diode-connected, first p-type device;
a diode-connected, second n-type device whose source is connected to ground; and
a second p-type device whose source is connected to the power-supply voltage, whose gate is connected to the drain of the diode-connected, second n-type device, and whose drain voltage is the “power OK” signal.

12. The integrated circuit of claim 11, wherein the integrated circuit is a field-programmable gate array.

13. (canceled)

14. (canceled)

15. An integrated circuit method, comprising:
generating, at a level-detector circuit, a “power OK” signal indicating whether a voltage for supplying a power supply voltage node of a ring oscillator is sufficiently high to prevent the ring oscillator from entering a meta-stable state;
receiving the “power OK” signal and a chip-level power-down control signal at logic circuitry and generating one or more control signals;
receiving, at switch circuitry, the one or more control signals and applying the voltage to the ring oscillator in response to the one or more control signals; and
enabling the ring oscillator to oscillate.
